(19) United States
(12) Patent Application Publication
(10) Pub. No.: US 2026/0173424 A1
(43) Pub. Date: Jun. 18, 2026

(54) SELF-ALIGNED DIRECT BACKSIDE SOURCE/DRAIN CONTACT STRUCTURE

(71) Applicant: International Business Machines Corporation, Armonk, NY (US)

(72) Inventors: Reinaldo Vega, Mahopac, NY (US); Ravikumar Ramachandran, Pleasantville, NY (US); Eric Miller, Albany, NY (US)

(21) Appl. No.: 18/985,883

(22) Filed: Dec. 18, 2024

(51) Int. Cl. H10D 30/01; H10D 30/00

(52) U.S. Cl. CPC H10D 30/0198; H10D 30/502

(57) ABSTRACT

A semiconductor device is provided that includes a transistor in which a self-aligned backside dielectric structure is in contact with one of the source/drain regions of the transistors and a self-aligned backside source/drain contact structure is in electrical contact with the other source/drain region of the transistor.

### BACKGROUND

The present application relates to semiconductor technology, and more particularly to a semiconductor device including a self-aligned backside dielectric structure and a self-aligned backside source/drain contact structure that are located above a backside back-end-of-line (BEOL) structure that is configured to deliver power from the backside of the device.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

A semiconductor device is provided that includes a transistor in which a self-aligned backside dielectric structure is in contact with one of the source/drain regions of the transistors and a self-aligned backside source/drain contact structure is in electrical contact with the other source/drain region of the transistor.

In one embodiment of the present application, the semiconductor device includes a transistor located on a semiconductor substrate and having a first source/drain region of a first critical dimension located on a first side of a gate structure and a second source/drain region of a second critical dimension located on a second side of the gate structure, in which the second side is opposite the first side. The semiconductor device further includes a backside dielectric structure having an upper dielectric portion of the second critical dimension in contact with the second source/drain region and a lower dielectric portion of a third critical dimension extending beneath the upper dielectric portion of the backside dielectric structure. The third critical dimension is greater than the second critical dimension. The semiconductor device further includes a backside source/drain contact structure having an upper contact portion of the first critical dimension in electrical contact with the first source/drain region and a lower contact portion of a fourth critical dimension extending beneath the lower contact portion of the backside source/drain contact structure. The fourth critical dimension is greater than the first critical dimension.

In another embodiment of the present application, the semiconductor device includes a transistor located on a semiconductor substrate and having a first source/drain region of a first critical dimension located on a first side of a gate structure and a second source/drain region of a second critical dimension located on a second side of the gate structure, in which the second side is opposite the first side. The semiconductor device further includes a backside dielectric structure having an upper dielectric portion of the second critical dimension in contact with the second source/drain region and a lower dielectric portion of a third critical dimension extending beneath the upper dielectric portion of the backside dielectric structure. The third critical dimension is greater than the second critical dimension. The semiconductor device further includes a backside source/drain contact structure having an upper contact portion in electrical contact with the first source/drain region and a lower contact portion beneath the upper contact portion of the backside source/drain contact structure, and a backside dielectric spacer located on a sidewall of the backside source/drain contact structure and contacting a bottommost surface of the first source/drain region.

### BRIEF DESCRIPTION OF THE DRAWINGS

FIG. 1 is a cross sectional view of an exemplary structure that can be employed in the present application, the exemplary structure including a nanosheet transistor located between a pair of diffusion break structures and including a gate structure wrapped around a vertical stack of spaced apart semiconductor channel material nanosheets and a pair of source/drain regions (i.e., a first source/drain region and a second source/drain region) extending partially into a semiconductor substrate, and a frontside BEOL structure electrically connected to the second source/drain region of the transistor by a frontside source/drain contact structure.

FIG. 2 is a cross sectional view of the exemplary structure of FIG. 1 after thinning the semiconductor substrate to a reveal a surface of the pair of diffusion break structures.

FIG. 3 is a cross sectional view of the exemplary structure of FIG. 2 after forming a patterned mask having an opening on a surface of the remaining semiconductor substrate.

FIG. 4 is a cross sectional view of the exemplary structure of FIG. 3 after forming a backside partial diffusion opening in the remaining semiconductor substrate which physically exposes a sub-surface of the second source/drain region of the transistor.

FIG. 5 is a cross sectional view of the exemplary structure of FIG. 4 after extending the backside partial diffusion opening by performing a partial etch back of the second source/drain region of the transistor, and then removing the patterned mask.

FIG. 6 is a cross sectional view of the exemplary structure of FIG. 5 after forming a backside dielectric structure in the extended backside partial diffusion opening.

FIG. 7 is a cross sectional view of the exemplary structure of FIG. 6 after forming a backside source/drain contact opening in the remaining semiconductor substrate that physically exposes a sub-surface of the first source/drain region of the transistor.

FIG. 8 is a cross sectional view of the exemplary structure of FIG. 7 after extending the backside source/drain contact opening by performing a partial etch back of the first source/drain region of the transistor.

FIG. 9 is a cross sectional view of the exemplary structure of FIG. 8 after performing a backside implant into the first source/drain region of the transistor.

FIG. 10 is a cross sectional view of the exemplary structure of FIG. 9 after forming a backside source/drain contact structure in the extended backside source/drain contact opening, and thereafter forming a backside BEOL structure.

FIG. 11 is a cross sectional view of the exemplary structure of FIG. 8 after forming a backside dielectric spacer and a backside source/drain contact structure in the extended backside source/drain contact opening, and thereafter forming a backside BEOL structure.

FIG. 12 is a cross sectional view of an exemplary structure of the present application in which a counter-doped region is located at a top and along a perimeter of the backside dielectric structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the present application, the terms “first”, “second”, “third”, and “fourth” used in before the term “critical dimension” is used for bookkeeping purposes and in no way describes any order of the critical dimension.

Direct backside source/drain contact structures are a key for scaling cell heights with backside BEOL structures that are configured for power delivery. Self-alignment of direct backside source/drain contact structures is desirable but is challenging. Also, backside contact implants are important for reducing backside contact resistance; however, this junction isolates remaining well regions resulting in floating wells. The present application discloses a semiconductor device including a transistor in which a self-aligned backside partial diffusion break structure is in contact with one of the source/drain regions of the transistors and a self-aligned backside source/drain contact structure is in electrical contact with the other source/drain region of the transistor. The self-aligned backside source/drain contact structure allows for backside contact implants while immunizing the semiconductor device from current variation due to the presence of a floating well.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. As used herein, a “source/drain” region can be a source region or a drain region depending on subsequent wiring and application of voltages during operation of the transistor. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

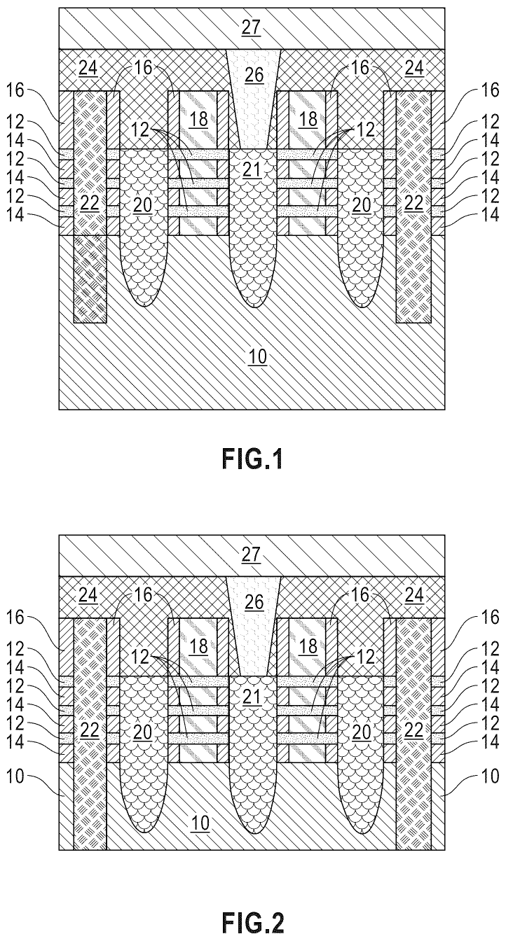

Referring first to FIG. 1, there is illustrated an exemplary structure that can be employed in the present application. The exemplary structure illustrated in FIG. 1 includes a nanosheet transistor (two of which are illustrated in FIG. 1 by way of one example) located between a pair of diffusion break structures 22. In some embodiments, the diffusion break structures 22 can be omitted. The nanosheet transistor includes a gate structure 18 wrapped around a vertical stack of spaced apart semiconductor channel material nanosheets 12 and a pair of source/drain regions (i.e., a first source/drain region 20 and a second source/drain region 21) extending partially into a semiconductor substrate 10. In the present application, the first source/drain region 20 is located on a first side of the gate structure 18 and the second source/drain region 21 is located on a second side of the gate structure 18, the second side of the gate structure 18 is opposite the first side of the gate structure 18. The exemplary structure illustrated in FIG. 1 further includes a frontside BEOL structure 27 electrically connected to the second source/drain region 21 of the transistor by a frontside source/drain contact structure 26. The frontside source/drain contact structure 26 is embedded in a multilayered frontside ILD structure 24. Collectively, the multilayered frontside ILD structure 24 and the frontside source/drain contact structure 26 provide a middle-of-the-line (MOL) level.

For the nanosheet transistor embodiment illustrated in the present application, the exemplary structure can also include gate spacer 16 and inner spacers 14. The gate spacer 16 is located along a sidewall of the gate structure 18 and inner spacers 14 are located beneath and at each of the ends of the semiconductor channel material nanosheets 12.

Each of the various components illustrated in FIG. 1 are now described in greater detail. The semiconductor substrate 10 includes at least a semiconductor device layer. The semiconductor device layer is an uppermost portion of the semiconductor substrate 10 in which a transistor will be formed thereon. The semiconductor substrate 10 can also include a semiconductor base layer and/or an etch stop layer. In one example, the semiconductor substrate 10 can include, from bottom to top, a semiconductor base layer, an etch stop layer and a semiconductor device layer. The semiconductor base layer of the semiconductor substrate 10 is composed of a first semiconductor material, and the semiconductor device layer of the semiconductor substrate 10 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer can be compositionally the same as, or compositionally different from, the first semiconductor material that provides the semiconductor base layer. In some embodiments of the present application, the etch stop layer of the semiconductor substrate 10 can be composed of a dielectric material such as, for example, silicon dioxide and/or boron nitride. In other embodiments of the present application, the etch stop layer of the semiconductor substrate 10 is composed of a third semiconductor material that is compositionally different from the first semiconductor material that provides the semiconductor base layer and the second semiconductor material that provides the semiconductor device layer. In one example, the semiconductor base layer is composed of silicon, the etch stop layer is composed of silicon dioxide, and the semiconductor device layer is composed of silicon. In another example, the semiconductor base layer is composed of silicon, the etch stop layer is composed of silicon germanium, and the semiconductor device layer is composed of silicon.

Each semiconductor channel material nanosheet 12 of the vertical stack of spaced apart semiconductor channel material nanosheets 12 includes a fourth semiconductor material. The fourth semiconductor material can be compositionally the same as, or compositionally different from, the second semiconductor material that provides the semiconductor device layer of the semiconductor substrate 10. In some embodiments, the fourth semiconductor material that provides each semiconductor channel material nanosheet 12 provides high channel mobility for NFET devices. In other embodiments, the fourth semiconductor material that provides each semiconductor channel material nanosheet 12 provides high channel mobility for PFET devices. In one example, each semiconductor channel material nanosheet 12 is composed of silicon. The number of semiconductor channel material nanosheets 12 present in each vertical stack of semiconductor channel material nanosheets 12 can vary and it not limited to three as exemplified in FIG. 1.

The gate spacer 16 and the inner spacer 14 are composed of a compositionally same or different spacer dielectric material. The dielectric spacer material can include, but is not limited to, silicon dioxide, SiN, SiBCN, SiOCN or SiOC.

The gate structure 18 includes a gate dielectric material and a gate electrode, both of which are not separately shown, but intended to be within the region defined by gate structure 18. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are measured in a vacuum unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

Each source/drain region (including the first source/drain region 20 and the second source/drain region 21) extends outward from a sidewall of the semiconductor channel material nanosheets 12 of a given vertical stack of semiconductor channel material nanosheets 12. Each source/drain region is composed of a fifth semiconductor material and a dopant. As used herein, a “source/drain” region can be a source region or a drain region depending on subsequent wiring and application of voltages during operation of the transistor. The fifth semiconductor material that provides the first source/drain region 20 and the second source/drain region 21 can be compositionally the same as, or compositionally different from, the fourth semiconductor material that provides each semiconductor channel material nanosheet 12. The dopant that is present in the first source/drain region 20 and the second source/drain region 21 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³. As is shown, each source/drain region including the first source/drain region 20 and the second source/drain region 21 extends beneath a topmost surface of the semiconductor substrate 10 and has a bottommost surface that is located in a sub-surface of the semiconductor substrate 10. The term “sub-surface” is used throughout the present application to denote a surface of a layer/structure that is located between a topmost surface and a bottommost surface of the layer/structure. In the present application, the depth of the first source/drain region 20 and the second source/drain region 21 in the semiconductor substrate 10 is less than a depth of the diffusion break structures 22 that are in the semiconductor substrate 10. In the present application, the first source/drain region 20 and the second source/drain region 21 have a greater dopant concentration than the semiconductor substrate 10. This aspect of the present application will allow the first source/drain region 20 and the second source/drain region 21 to be etched selective to the semiconductor substrate 10.

Each diffusion break structure 22 is composed of at least one trench dielectric material. An example of a trench dielectric material that can be used in providing the diffusion break structure 22 is silicon oxide. The diffusion break structure 22 can be referred to as a frontside dielectric structure or a frontside isolation structure. Each diffusion break structure 22 is formed between the gate spacer 16 and the inner spacers 14, passes through a middle portion of a vertical stack of spaced apart semiconductor nanosheets 12 and lands on a sub-surface of semiconductor substrate 10. Each diffusion break structure 22 has a depth in the semiconductor substrate 10 that is greater than a depth of the source/drain regions in the semiconductor substrate 10. Each diffusion break structure 22 can be formed by lithography and etching a trench that extends into the semiconductor substrate 10. The trench is then filled with a trench dielectric material. The filling of the trench can include deposition and planarization. Each diffusion break structure 22 is used to electrically isolate at least one transistor from another transistor. The diffusion break structure 22 can be used to reduce the distance between active device areas and enable area-scaling.

The multilayered frontside ILD structure 24 includes two frontside ILD layers; the first frontside ILD layer represents a lower portion of the multilayered frontside ILD structure 24, while the second frontside ILD layer represent an upper portion of the multilayered frontside ILD structure 24. The first frontside ILD layer is composed of a first ILD material, while the second frontside ILD layer is composed of a second ILD material. The second ILD material can be compositionally the same as, or compositionally different from, the first ILD material. An ILD material is a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The frontside source/drain contact structure 26 is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside source/drain contact structure 26 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside BEOL structure 27 is composed of an interconnect dielectric region having frontside metal wiring embedded therein; the frontside metal wiring present in the frontside BEOL structure 27 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy.

Carrier wafer (not shown) can be present on top of the frontside BEOL structure 27. The carrier wafer can include a semiconductor material as exemplified above. Carrier wafer is bonded to the frontside BEOL structure 27 by a bonding dielectric layer (not shown). Illustrative examples of dielectric materials that are used as the bonding dielectric layer include, but are not limited to, tetraethyl orthosilicate (TEOS), SiO₂, silicon carbon nitride (SiCN) and/or carbon-doped silicon oxide (SiCOH).

The exemplary structure shown in FIG. 1 can be formed utilizing any well-known nanosheet transistor device fabrication process. The nanosheet transistor device fabrication process typically includes the use of a sacrificial gate structure which is used in defining a nanosheet stack of alternating sacrificial semiconductor nanosheets and semiconductor channel material nanosheets. After defining the nanosheet stack, the sacrificial gate structure is removed to reveal the underlying nanosheet stack and thereafter each sacrificial semiconductor material nanosheet of the nanosheet stack is removed and thereafter a gate structure is formed wrapping around each of the suspended semiconductor channel material nanosheets of the nanosheet stack.

Referring now to FIG. 2, there is illustrated the exemplary structure of FIG. 1 after thinning the semiconductor substrate 10 to a reveal a surface of each diffusion break structures 22. In embodiments in which no diffusion break structures 22 are present, the thinning of the semiconductor substrate 10 does not reveal the first source/drain region 20 or the second source/drain region 21 of the transistor; thus a portion of the semiconductor substrate 10 remains beneath the first source/drain region 20 and the second source/drain region 21. Prior to thinning the semiconductor substrate 10, the exemplary structure illustrated in FIG. 1 is flipped 180° to physically expose a backside of the exemplary structure. For clarity, the flipping step is not shown in the drawings. Flipping can be performed by hand or by utilizing a mechanical means such as, for example, a robot arm. After flipping, the semiconductor substrate 10 is thinned utilizing one or more material removal processes that is/are selective in removing a portion of the semiconductor substrate 10. The one or more material process can include an etching process, a planarization process such as, for example, chemical mechanical planarization (CMP) or a combination of etching and planarization. In embodiments, the semiconductor base layer and the etch stop layer are removed, and then the semiconductor device layer is thinned. Note that since the first source/drain region 20 and the second source/drain region 21 have a shallower depth in the semiconductor substrate 10, a portion of the semiconductor substrate 10 remains beneath each of the first source/drain region 20 and the second source/drain region 21.

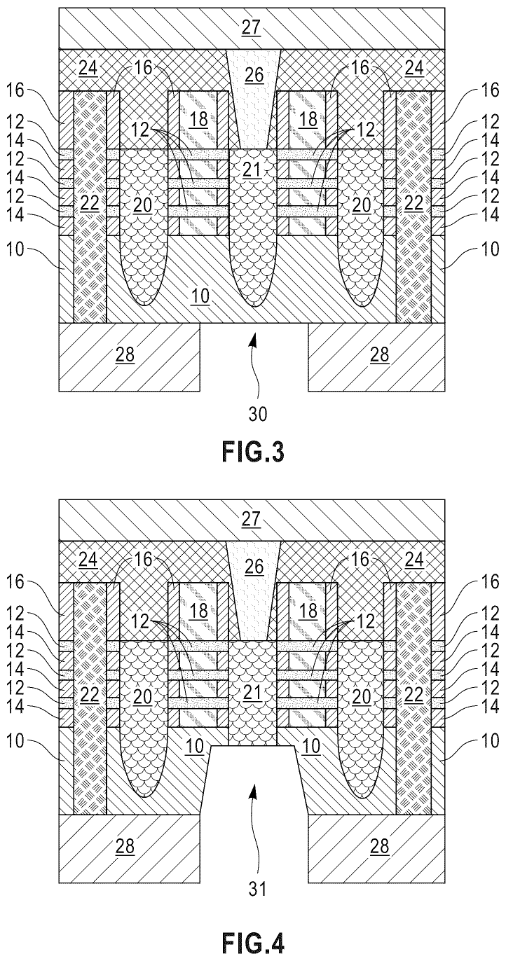

Referring now to FIG. 3, there is illustrated the exemplary structure of FIG. 2 after forming a patterned mask 28 having an opening 30 on a surface of the remaining semiconductor substrate 10. In some embodiments, the patterned mask 28 is composed of a dielectric hard mask material such as, for example, silicon nitride, silicon oxide, silicon oxynitride or any multilayered stack thereof. In embodiments in which the patterned mask 28 is composed of a dielectric hard mask material, the patterned mask 28 can be formed by depositing a layer of dielectric hard mask material on remaining semiconductor substrate 10. The depositing the layer of dielectric hard mask material includes, for example, chemical vapor deposition (CVD), plasma enhanced chemical vapor deposition (PECVD), physical vapor deposition (PVD) or atomic layer deposition (ALD). After depositing the layer of dielectric hard mask material, the as-deposited layer of dielectric hard mask material is patterned by lithography and etching. Lithography includes depositing a photoresist material on a layer/structure that needs to be patterned, then exposing the as-deposited photoresist material to a desired pattern of irradiation and thereafter developing the exposed photoresist material to provide a patterned photoresist material on the layer/structure that needs to be patterned. An etch including a dry etching process and/or a chemical wet etching process is then used to transfer the patterned from the patterned photoresist material into the underlying layer/structure. Dry etching can include, for example, reactive ion etching (RIE), plasma etching or ion beam etching (IBE). Chemical wet etching includes the use of a chemical etchant that is selective in removing one material as compared to another material. The patterned photoresist material is removed after transferring the patterned into the underlying layer/structure utilizing a conventional resist removal process such as, for example ashing. In the illustrated embodiment, opening 30 is formed in the as-deposited layer of dielectric hard mask material which coincides with the location of the second source/drain region 21.

In other embodiments, the patterned mask 28 can be composed of a photoresist material. In embodiments in which the patterned mask 28 is composed of a photoresist material, the patterned mask can be formed by utilizing lithography as defined above.

Referring now to FIG. 4, there is illustrated the exemplary structure of FIG. 3 after forming a backside opening 31 in the remaining semiconductor substrate 10 which physically exposes a sub-surface of the second source/drain region 21 of the transistor. The forming of the backside opening 31 includes an etch that is selective in removing the remaining semiconductor substrate 10 that is not protect by the patterned mask 28; the etch occurs through opening 30 that is present in patterned mask 28. During this etch, a portion of the second source/drain region 21 that is present in the semiconductor substrate 10 can also be removed as is illustrated in FIG. 4.

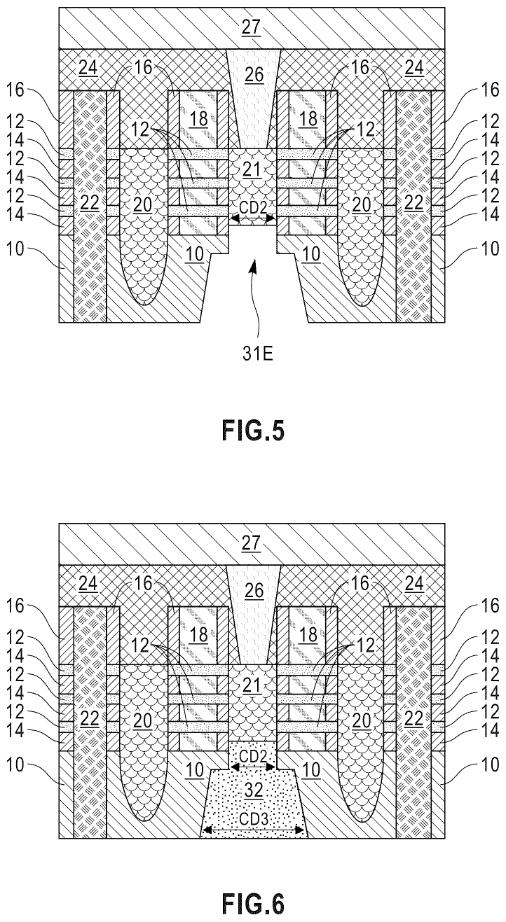

Referring now to FIG. 5, there is illustrated the exemplary structure of FIG. 4 after extending the backside opening 31 by performing a partial etch back of the second source/drain region 21 of the transistor, and then removing the patterned mask 28. This extending step provides an extended opening 31E as shown in FIG. 5. The partial etch back process is selective in removing a portion of the second source/drain region 21. In one example, the partial etch back process includes the use of HF as a chemical etchant. In another example, the partial etch back process includes the use of a mixture of HCL and HNO₃ as the chemical etchant. The second source/drain region 21 that remains after this etch has a bottommost surface that is typically located between a topmost surface of the semiconductor substrate 10 and a bottommost surface of a bottommost semiconductor channel material nanosheet within the vertical stack of spaced apart semiconductor channel material nanosheets 12. Stated in other terms, the second source/drain region 21 that remains after this etch is located above a topmost surface of the semiconductor substrate 10. The second source/drain region 21 that remains after this etch has a second critical dimension, CD2, i.e., lateral width.

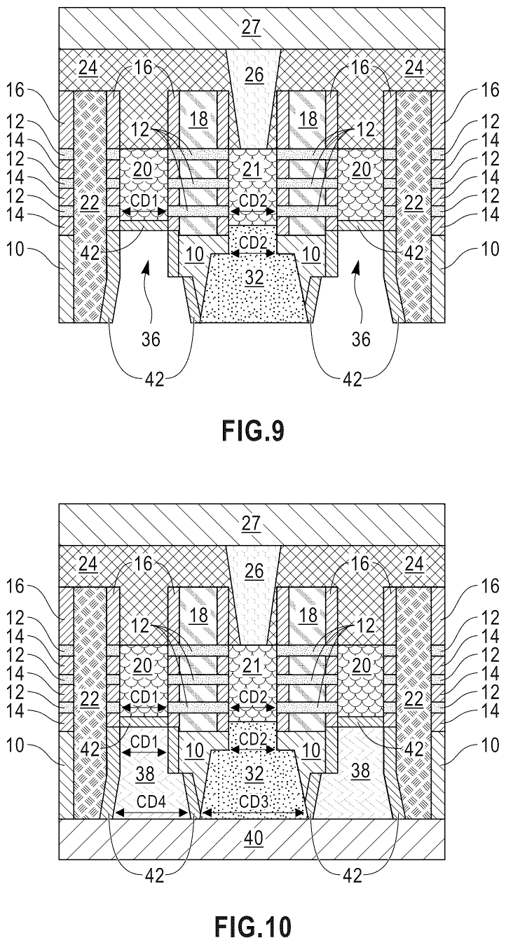

After forming the extended backside opening 31E, the patterned mask 28 can be removed utilizing a material removal process that is selective in removing the dielectric hard mask material or the photoresist material that provides the patterned mask 28. In some embodiments, and prior to removing patterned mask 28, an implant (not shown) can be performed at this stage of the present application. In other embodiments, this implant is omitted. The implant introduces a dopant (i.e., n-type dopant or p-type dopant) that has an opposite polarity than (i.e., of a opposite conductivity type as) the second source/drain region 21 into a bottom portion of the second source/drain region 21 and along the sidewalls of the semiconductor substrate 10. The implant can be performed utilizing implantation conditions that are well known in the semiconductor industry. An anneal can be employed in some embodiments. In embodiments in which this implant is performed, counter-doped region 44 (see, for example, FIG. 12) is formed and it would be present at the top and along the perimeter of the backside dielectric structure 32 to be subsequently formed. The counter doped region 44 can be present in a structure which includes, or does not include, doped region 42 (as described below with respect to FIG. 9).

Referring now to FIG. 6, there is illustrated the exemplary structure of FIG. 5 after forming a backside dielectric structure 32 in the extended opening 31E. The backside dielectric structure 32 can also be referred to a backside isolation structure or a backside partial break structure. The backside dielectric structure 32 is composed of a dielectric material such as, for example, silicon oxide, silicon nitride, or silicon oxynitride. In some embodiments, the backside dielectric structure 32 is composed of a single dielectric material. In other embodiments, the backside dielectric structure 32 is composed of at least two compositionally different dielectric materials. The backside dielectric structure 32 can be formed by deposition of a dielectric material, followed by a planarization process. The depositing of the dielectric material includes, for example, CVD, PECVD or ALD. The backside dielectric structure 32 has an upper dielectric portion that has the second critical dimension, CD2, and a lower dielectric portion (extending beneath the upper dielectric portion of the backside dielectric structure 32) that has a third dimension, CD3, that is greater than the second critical dimension, CD2. Since the upper dielectric portion of the backside dielectric structure 32 has a critical dimension that is equal to that of the second source/drain region 21, the upper dielectric portion of the backside dielectric structure 32 is self-aligned to, and is in contact with, a bottommost surface of the second source/drain region 21.

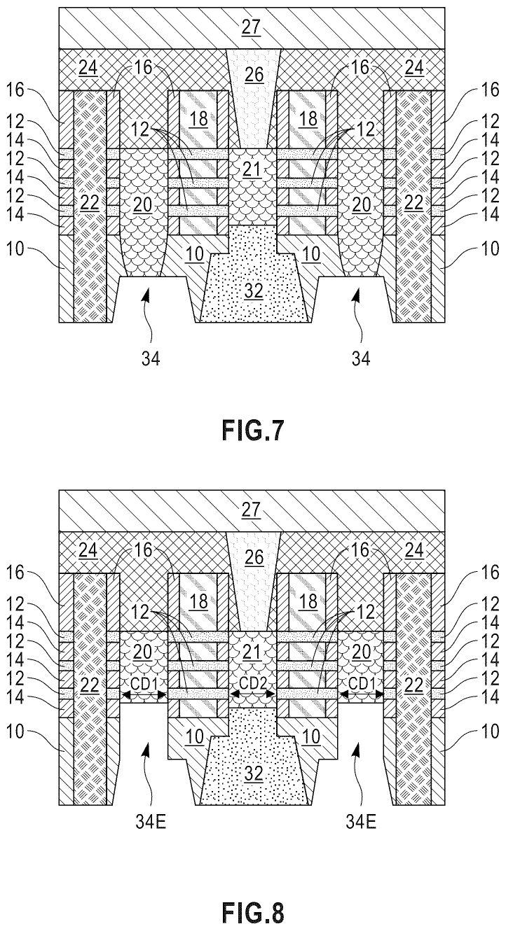

Referring now to FIG. 7, there is illustrated the exemplary structure of FIG. 6 after forming a backside source/drain contact opening 34 in the remaining semiconductor substrate 10 that physically exposes a sub-surface of the first source/drain region 20 of the transistor. The forming of backside source/drain contact opening 34 includes a backside contact etch. During backside contact etch, a portion of the first source/drain region 20 that is present in the semiconductor substrate 10 can also be removed as is illustrated in FIG. 7.

Referring now to FIG. 8, there is illustrated the exemplary structure of FIG. 7 after extending the backside source/drain contact opening 34 by performing a partial etch back of the first source/drain region 20 of the transistor. This extending step provides an extended backside source/drain contact opening 34E as shown in FIG. 8. The partial etch back process is selective in removing a portion of the first source/drain region 20. In one example, the partial etch back process includes the use of HF as a chemical etchant. In another example, the partial etch back process includes the use of a mixture of HCL and HNO₃ as the chemical etchant. The first source/drain region 20 that remains after this etch typically has a bottommost surface that is located between a topmost surface of the semiconductor substrate 10 and a bottommost surface of a bottommost semiconductor channel material nanosheet within the vertical stack of spaced apart semiconductor channel material nanosheets 12. Stated in other terms, the first source/drain region 20 are located above a topmost surface of the semiconductor substrate 10. The first source/drain region 20 that remains after this etch has a first critical dimension, CD1. In some embodiments, the first critical dimension, CD1, of the first source/drain region 20 is equal to the second critical dimension, CD2, of the second source/drain region 21.

Referring now to FIG. 9, there is illustrated the exemplary structure of FIG. 8 after performing a backside implant 36 into the first source/drain region 20 of the transistor. The backside implant 36 introduces an n-type dopant or p-type dopant into the first source/drain region 20 and in the semiconductor substrate 10 that is physically exposed by the extended backside source/drain contact opening 34E. Notably, this backside implant forms doped region 42 as is shown in FIG. 9. Doped region 42 is of the same conductivity type as the first source/drain region 20. It is noted that doped region 42 will be present along a top and sidewalls of the subsequently formed backside source/drain contact structure 38. The type of dopant matches the dopant that is already present in the first source/drain region 20. The backside implant 36 can be performed utilizing implantation conditions that are well known in the semiconductor industry. An anneal can follow the backside implant 36. The anneal is performed at temperatures well known in the art. In some embodiments, the backside implant 36 can be omitted.

Referring now to FIG. 10, there is illustrated the exemplary structure of FIG. 9 after forming a backside source/drain contact structure 38 in the extended backside source/drain contact opening 34E, and thereafter forming a backside BEOL structure 40. The backside source/drain contact structure 38 is composed of a contact conductor material such as for example, a conductive metal such as W, Cu, Al, Co, Ru, Mo, Os, Ir, Rh, or an alloy thereof. The backside source/drain contact structure 38 can be formed by deposition of the contact conductor material, followed by a planarization process. The deposition of the contact conductor material can include, for example, CVD, PECVD, ALD, sputtering or plating. In this embodiment, the backside source/drain contact structure 38 has an upper backside contact that has the first critical dimension, CD1, and a lower backside contact portion that has a fourth critical dimension, CD4, in which the fourth critical dimension, CD4, is greater than the first critical dimension, CD1. The upper contact portion of the backside source/drain contact structure 38 is thus self-aligned to, and is in electrical contact with, a bottommost surface of the first source/drain region 20.

Although the present application describes forming the backside dielectric structure 32 prior forming the backside source/drain contact structure 38, the order of forming the backside dielectric structure 32 and the backside source/drain contact structure 38 can be reversed such that the backside source/drain contact structure 38 is formed prior to the backside dielectric structure 32.

The backside BEOL structure 40 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 40 can be formed utilizing any well-known BEOL process including a damascene process or a subtractive metal etch process.

FIG. 10 illustrates a semiconductor device in accordance with an embodiment of the present application. Notably, the semiconductor illustrated in FIG. 10 includes a transistor located on semiconductor substrate 10 and having first source/drain region 20 of a first critical dimension, CD1, located on a first side of gate structure 18 and second source/drain region 21 of a second critical dimension, CD2, located on a second side of the gate structure 18, in which the second side is opposite the first side. The semiconductor device further includes backside dielectric structure 32 having an upper dielectric portion of the second critical dimension, CD2, in contact with the second source/drain region 21 and a lower dielectric portion of a third critical dimension, CD3, extending beneath the upper dielectric portion of the backside dielectric structure. The third critical dimension, CD3, is greater than the second critical dimension, CD2. The semiconductor device further includes backside source/drain contact structure 38 having an upper contact portion of the first critical dimension, CD1, in electrical contact with the first source/drain region and a lower backside contact portion of a fourth critical dimension, CD4, extending beneath the lower contact portion of the backside source/drain contact structure 38. The fourth critical dimension, CD4, is greater than the first critical dimension, CD1.

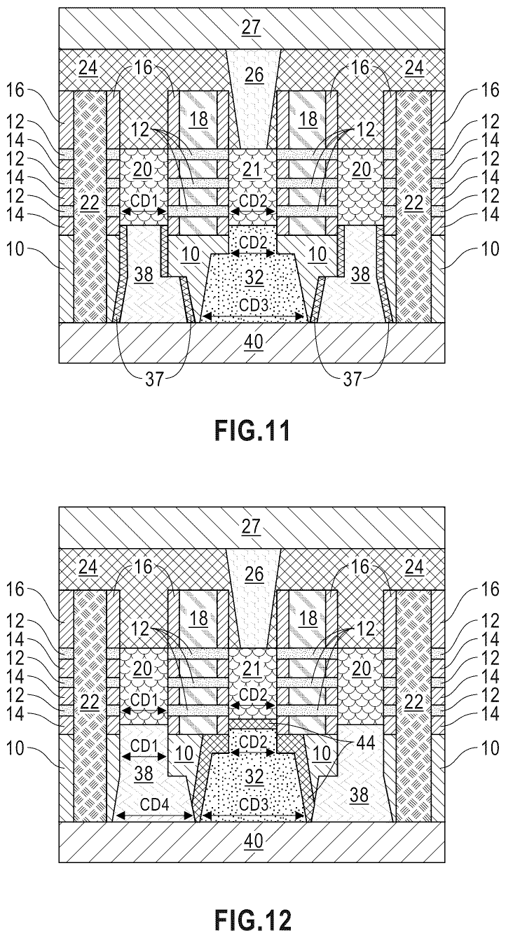

As is illustrated in FIG. 10 (and also FIG. 11), each diffusion break structure 22 has a topmost surface that is substantially coplanar with a topmost surface of the transistor and a bottommost surface that is substantially coplanar with a bottommost surface of both backside dielectric structure 32 and the backside source/drain contact structure 38. In some embodiments and as also illustrated in FIG. 10 (and FIG. 11), each diffusion break structure 22, backside dielectric structure 32 and the backside source/drain contact structure 38 land on a surface of the backside BEOL structure 40. In other embodiments, various backside ILD layers can be positioned between the backside BEOL structure 40 and each of the diffusion break structure 22, backside dielectric structure 32 and the backside source/drain contact structure 38. The various backside ILD layers typically contain electrically conductive structures embedded therein.

In some embodiments, and as illustrated in FIGS. 10-11, the upper dielectric portion of the backside dielectric structure 32 and the upper contact portion of the backside source/drain contact structure 38 both extend above the topmost surface of the semiconductor substrate 10.

Referring now to FIG. 11, there is illustrated the exemplary structure of FIG. 9 after forming a backside dielectric spacer 37 and a backside source/drain contact structure 38 in the extended backside source/drain contact opening 34E, and thereafter forming backside BEOL structure 40. In some embodiments, various backside ILD layer (with electrically conductive structures embedded therein) can be formed after forming the backside dielectric spacer 37 and the backside source/drain contact structure 38 and prior to forming the backside BEOL structure 40. The backside source/drain contact structure 38 and the backside BEOL structure 40 that are used for this embodiment are the same as that mentioned above in regard to the exemplary structure illustrated in FIG. 10. The backside dielectric spacer 37 is composed of a spacer dielectric material such as, for example, silicon dioxide, SiN, SiBCN, SiOCN or SiOC. The backside dielectric spacer 37 can be formed by deposition of the spacer dielectric material, followed by a planarization process. The planarization process is typically performed after filling the remaining of the extended backside source/drain contact opening 34E with the contact conductor material that provides the backside source/drain contact structure 38. The backside dielectric spacer 37 is located on a sidewall of the backside source/drain contact structure 38 and directly contact a bottommost surface of the first source/drain region 20. In this embodiment, the backside dielectric spacer 37 aids in providing a backside source/drain contact structure 38 that is self-aligned to the first source/drain region 20.

Notably, FIG. 11 illustrates another semiconductor device in accordance with the present application. The semiconductor device illustrated in FIG. 11 includes a transistor located on semiconductor substrate 10 and having first source/drain region 20 of a first critical dimension, CD1, located on a first side of gate structure 18 and second source/drain region 21 of a second critical dimension, CD2, located on a second side of the gate structure 18, in which the second side is opposite the first side. The semiconductor device further includes backside dielectric structure 32 having an upper dielectric portion of the second critical dimension, CD2, in contact with the second source/drain region 21 and a lower dielectric portion of a third critical dimension, CD3, extending beneath the upper dielectric portion of the backside dielectric structure 32. The third critical dimension, CD3, is greater than the second critical dimension,

CD2. The semiconductor device further includes backside source/drain contact structure 38 having an upper backside source/drain contact portion in electrical contact with the first source/drain region 20 and a lower backside source/drain contact portion beneath the lower backside source/drain contact portion, and backside dielectric spacer 37 located on a sidewall of the backside source/drain contact structure 38 and contacting a bottommost surface of the first source/drain region 20. Although not shown, counter-doped region 44 can be located on top of and along a perimeter of the backside dielectric structure 32. In this embodiment, the doped region 42 can be omitted.

Referring now to FIG. 12, there is illustrated a structure similar to FIG. 10, except that counter-doped region 44 is present at the top and along the perimeter of the backside dielectric structure 22. It is noted that although no doped region 42 is shown in FIG. 12, the present application works in cases in which doped region 42 is present on top of and along a perimeter of the backside source/drain contact structures 38.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a transistor located on a semiconductor substrate and having a first source/drain region of a first critical dimension located on a first side of a gate structure and a second source/drain region of a second critical dimension located on a second side of the gate structure, wherein the second side is opposite the first side;
a backside dielectric structure having an upper dielectric portion of the second critical dimension in contact with the second source/drain region and a lower dielectric portion of a third critical dimension extending beneath the upper dielectric portion of the backside dielectric structure, wherein the third critical dimension is greater than the second critical dimension; and
a backside source/drain contact structure having an upper contact portion of the first critical dimension in electrical contact with the first source/drain region and a lower contact portion of a fourth critical dimension extending beneath the upper contact portion of the backside source/drain contact structure, wherein the fourth critical dimension is greater than the first critical dimension.

2. The semiconductor device of claim 1, wherein each of the first source/drain region and the second source/drain region has a bottommost surface that extends above a topmost surface of the semiconductor substrate.

3. The semiconductor device of claim 2, wherein the upper dielectric portion of the backside dielectric structure and the upper contact portion of the backside source/drain contact structure both extend above the topmost surface of the semiconductor substrate.

4. The semiconductor device of claim 1, wherein the first critical dimension is equal to the second critical dimension.

5. The semiconductor device of claim 1, further comprising a frontside back-end-of-the-line (BEOL) structure located above the transistor.

6. The semiconductor device of claim 5, wherein the second source/drain region is electrically connected to the frontside BEOL structure by a frontside source/drain contact structure.

7. The semiconductor device of claim 1, further comprising a backside BEOL structure located beneath the backside source/drain contact structure and the backside dielectric structure.

8. The semiconductor device of claim 7, wherein both the backside dielectric structure and the backside source/drain contact structure are in direct physical contact with the backside BEOL structure.

9. The semiconductor device of claim 1, wherein the backside dielectric structure is composed of at least two compositionally different dielectric materials.

10. The semiconductor device of claim 1, further comprising a doped region having a same conductivity as the first source/drain region located at a top and along a perimeter of the backside source/drain contact structure.

11. The semiconductor device of claim 1, further comprising a counter-doped region having a different conductivity than the second source/drain region located at a top and along a perimeter of the backside dielectric structure.

12. A semiconductor device comprising:
a transistor located on a semiconductor substrate and having a first source/drain region of a first critical dimension located on a first side of a gate structure and a second source/drain region of a second critical dimension located on a second side of the gate structure, wherein the second side is opposite the first side;
a backside dielectric structure having an upper dielectric portion of the second critical dimension in contact with the second source/drain region and a lower dielectric portion of a third critical dimension extending beneath the upper dielectric portion of the backside dielectric structure, wherein the third critical dimension is greater than the second critical dimension;
a backside source/drain contact structure having an upper contact portion in electrical contact with the first source/drain region and a lower contact portion beneath the upper contact portion of the backside source/drain contact structure; and
a backside spacer located on a sidewall of the backside source/drain contact structure and contacting a bottommost surface of the first source/drain region.

13. The semiconductor device of claim 12, wherein each of the first source/drain region and the second source/drain region has a bottommost surface that extends above a topmost surface of the semiconductor substrate.

14. The semiconductor device of claim 13, wherein the upper dielectric portion of the backside dielectric structure and the upper contact portion of the backside source/drain contact structure both extend above the topmost surface of the semiconductor substrate.

15. The semiconductor device of claim 12, further comprising a frontside back-end-of-the-line (BEOL) structure located above the transistor.

16. The semiconductor device of claim 15, wherein the second source/drain region is electrically connected to the frontside BEOL structure by a frontside source/drain contact structure.

17. The semiconductor device of claim 12, further comprising a backside BEOL structure located beneath the backside source/drain contact structure and the backside dielectric structure.

18. The semiconductor device of claim 17, wherein both the backside dielectric structure and the backside source/drain contact structure are in direct physical contact with the backside BEOL structure.

19. The semiconductor device of claim 12, wherein the backside dielectric structure is composed of at least two compositionally different dielectric materials.

20. The semiconductor device of claim 12, further comprising a counter-doped region having a different conductivity than the second source/drain region located at a top and along a perimeter of the backside dielectric structure.
